(19) United States
(12) Patent Application Publication
(10) Pub. No.: US 2024/0304557 A1
(43) Pub. Date: Sep. 12, 2024

(54) SEMICONDUCTOR PACKAGE

(71) Applicant: Samsung Electronics Co., Ltd., Suwon-si (KR)

(72) Inventors: Gyujin CHOI, Suwon-si (KR); Dahee KIM, Suwon-si (KR); Jaeean LEE, Suwon-si (KR); Taehoon LEE, Suwon-si (KR)

(21) Appl. No.: 18/479,820

(22) Filed: Oct. 2, 2023

(30) Foreign Application Priority Data
Mar. 9, 2023 (KR) 10-2023-0031092

(51) Int. Cl. H01L 23/538; H01L 23/00; H01L 23/31; H01L 23/498; H01L 23/552; H01L 25/065

(52) U.S. Cl. CPC H01L 23/5383; H01L 23/3128; H01L 23/49811; H01L 23/5385; H01L 23/5386; H01L 23/552; H01L 24/13; H01L 24/16; H01L 25/0652; H01L 24/32; H01L 24/73; H01L 2224/13; H01L 2224/16145; H01L 2224/16227; H01L 2224/32145; H01L 2224/73204

(57) ABSTRACT

A semiconductor package includes a first redistribution structure in which at least one first redistribution layer and at least one first insulating layer are alternately layered; a first semiconductor chip disposed on an upper surface of the first redistribution structure; a second semiconductor chip having a lower portion surrounded by the first redistribution structure; a first encapsulant disposed on the upper surface of the first redistribution structure to encapsulate the first semiconductor chip; a second encapsulant encapsulating the second semiconductor chip and having a lower portion surrounded by the first redistribution structure; and a conductive support layer supporting the second semiconductor chip and the second encapsulant on an upper surface of the second semiconductor chip.

### CROSS-REFERENCE TO RELATED APPLICATION(S)

This application claims priority under 35 U.S.C. § 119 to Korean Patent Application No. 10-2023-0031092, filed on Mar. 9, 2023, in the Korean Intellectual Property Office, the disclosure of which is herein incorporated by reference in its entirety.

### TECHNICAL FIELD

The present inventive concept relates to a semiconductor package, and more particularly to a semiconductor package including a structure increasing layout flexibility.

### DISCUSSION OF RELATED ART

In general, a semiconductor chip may be implemented in a semiconductor package such as a wafer level package (WLP) or a panel level package (PLP), and the semiconductor package may be used as an electronic component of a device.

The semiconductor package may include a redistribution layer for electrically connecting the semiconductor chip to the device or a printed circuit board. The redistribution layer may have a horizontally extended structure, which may be finer than a wiring of a wiring layer of a general printed circuit board.

The redistribution layer may be electrically connected to a bump, which may vertically extend an electrical connection path. An under-bump-metallurgy (UBM) may efficiently improve the electrical connection between the redistribution layer and the bumps.

As semiconductor chips become increasingly complex and the performance of the semiconductor chips gradually increases, a degree of integration of a semiconductor package including one or more of these semiconductor chips may gradually increase, and a size of the semiconductor package may be reduced, as compared to a unit of performance.

In the design of the semiconductor chips, there may be a balance between higher performance semiconductor packages and design freedom in the semiconductor chips. For example, as an overall degree of freedom in the design of the semiconductor chips increases, a size difference between the semiconductor chips may increase, efficiency in an arrangement of the semiconductor chips in a semiconductor package may decrease, and a size or a thickness of the semiconductor package may increase. Accordingly, miniaturization efficiency, durability, and reliability of the semiconductor package may need to be balanced with the overall degree of freedom in design of the semiconductor chips.

### SUMMARY

An aspect of the present inventive concept is to provide a semiconductor package enabling an increased degree of freedom in the design of semiconductor chips, while securing at least one of miniaturization efficiency, durability, or reliability in the semiconductor package.

According to an aspect of the present inventive concept, a semiconductor package includes a first redistribution structure in which at least one first redistribution layer and at least one first insulating layer are alternately layered; a first semiconductor chip disposed on an upper surface of the first redistribution structure; a second semiconductor chip having a lower portion surrounded by the first redistribution structure; a first encapsulant disposed on the upper surface of the first redistribution structure to encapsulate the first semiconductor chip; a second encapsulant encapsulating the second semiconductor chip and having a lower portion surrounded by the first redistribution structure; and a conductive support layer supporting the second semiconductor chip and the second encapsulant on an upper surface of the second semiconductor chip.

According to an aspect of the present inventive concept, a semiconductor package includes a first redistribution structure in which at least one first redistribution layer and at least one first insulating layer are alternately layered; a first semiconductor chip disposed on an upper surface of the first redistribution structure; a second semiconductor chip having a lower portion surrounded by the first redistribution structure; a first encapsulant disposed on the upper surface of the first redistribution structure to encapsulate the first semiconductor chip; a second encapsulant encapsulating the second semiconductor chip and having a lower portion surrounded by the first redistribution structure; and a plurality of bumps having a first set of the plurality of bumps electrically connected to the first semiconductor chip and a second set of the plurality of bumps electrically connected to the second semiconductor chip, wherein a first portion of the lower portion of the second encapsulant is disposed between the second set of the plurality of bumps and the second semiconductor chip, and a second portion of the lower portion of the second encapsulant is disposed between the second set of the plurality of bumps and the first redistribution structure.

According to an aspect of the present inventive concept, a semiconductor package includes a first redistribution structure in which at least one first redistribution layer and at least one first insulating layer are alternately layered; a first semiconductor chip disposed on an upper surface of the first redistribution structure; a second semiconductor chip having a lower portion surrounded by the first redistribution structure; a core insulating layer having a first cavity in which the first semiconductor chip is disposed and a second cavity in which the second semiconductor chip is disposed, and disposed on the upper surface of the first redistribution structure; a first encapsulant disposed on the upper surface of the first redistribution structure to encapsulate the first semiconductor chip; a second encapsulant encapsulating the second semiconductor chip and having a lower portion surrounded by the first redistribution structure; a conductive support layer supporting the second semiconductor chip and the second encapsulant on an upper surface of the second semiconductor chip; and a plurality of bumps having a first set of the plurality of bumps electrically connected to the first semiconductor chip and a second set of the plurality of bumps electrically connected to the second semiconductor chip, wherein a slope of a side surface of the second cavity has a lower slope than a slope of a side surface of the first cavity, the first encapsulant is in direct contact with the conductive support layer or the second encapsulant, the first encapsulant is disposed on an upper surface of the core insulating layer, a first portion of the lower portion of the second encapsulant is disposed between the second set of the plurality of bumps and the second semiconductor chip, and an upper portion of the second encapsulant is disposed between the second set of the plurality of bumps and the first redistribution structure.

### BRIEF DESCRIPTION OF THE DRAWINGS

The above and other aspects, features, and advantages of the present inventive concept will be more clearly understood from the following detailed description, taken in conjunction with the accompanying drawings, in which:

FIG. 1A and FIG. 1B are cross-sectional views of a semiconductor package according to an embodiment, taken along an X-Z plane.

FIG. 1C and FIG. 1D are cross-sectional views of a semiconductor package and an arrangement height (or a thickness) of a first semiconductor chip that may be included in the semiconductor package, according to an embodiment, are changed.

FIG. 1E is a cross-sectional view illustrating a semiconductor package and a shielding wall that may be included in the semiconductor package according to an embodiment.

FIG. 1F and FIG. 1G are cross-sectional views illustrating a structure in which a second redistribution structure is omitted from a semiconductor package according to an embodiment.

FIG. 2A and FIG. 2B are cross-sectional views illustrating a semiconductor package and passive components that may be included in the semiconductor package according to an embodiment.

FIG. 2C and FIG. 2D are cross-sectional views illustrating a structure in which a semiconductor package and first semiconductor chips that may be included in the semiconductor package, according to an embodiment, vertically overlap.

FIG. 3 is a cross-sectional view of a semiconductor package according to an embodiment, taken along an X-Y plane.

FIG. 4A, FIG. 4B, FIG. 4C, FIG. 4D, FIG. 4E, FIG. 4F, FIG. 4G, and FIG. 4H are cross-sectional views illustrating a method of manufacturing the semiconductor package of FIG. 1A.

FIG. 5A, FIG. 5B, FIG. 5C, and FIG. 5D are cross-sectional views illustrating a method of manufacturing the semiconductor package of FIG. 1C.

### DETAILED DESCRIPTION

The following detailed description of the present disclosure refers to the accompanying drawings, which illustrate, by way of example, specific embodiments in which the present disclosure may be practiced. Embodiments are described in sufficient detail to enable those skilled in the art to practice the invention. It should be understood that various embodiments of the present disclosure may be different, but need not be mutually exclusive. For example, certain features, structures, and characteristics described herein may be implemented in other embodiments without departing from the spirit and scope of the present disclosure in connection with one embodiment. It may be also to be understood that the position or arrangement of the individual components within a disclosed embodiment may be varied without departing from the spirit and scope of the present disclosure. The following detailed description is, therefore, not to be taken in a limiting sense. In the drawings, like reference numerals refer to the same or similar functions throughout the several views.

Hereinafter, embodiments of the present disclosure will be described in detail with reference to the accompanying drawings such that those skilled in the art may carry out the present disclosure.

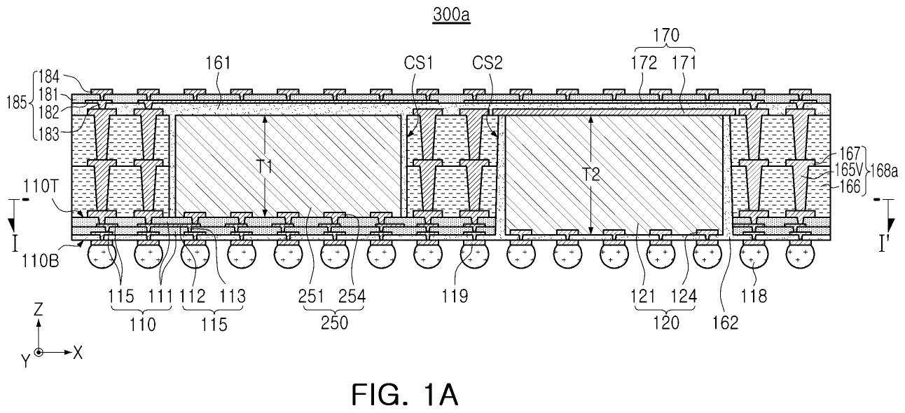

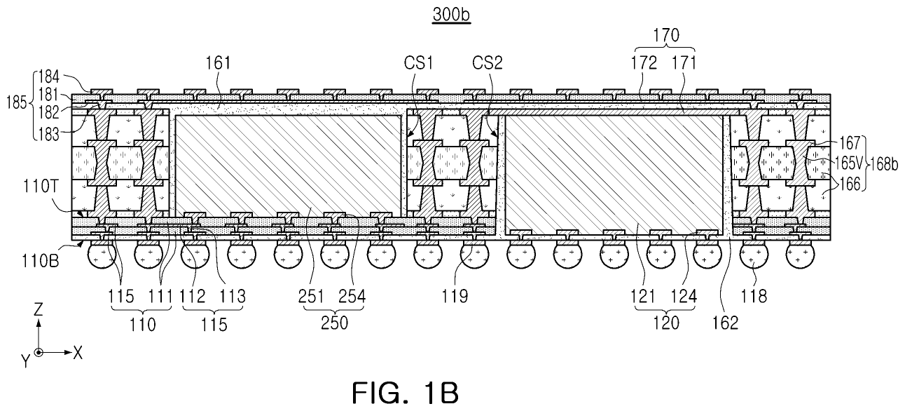

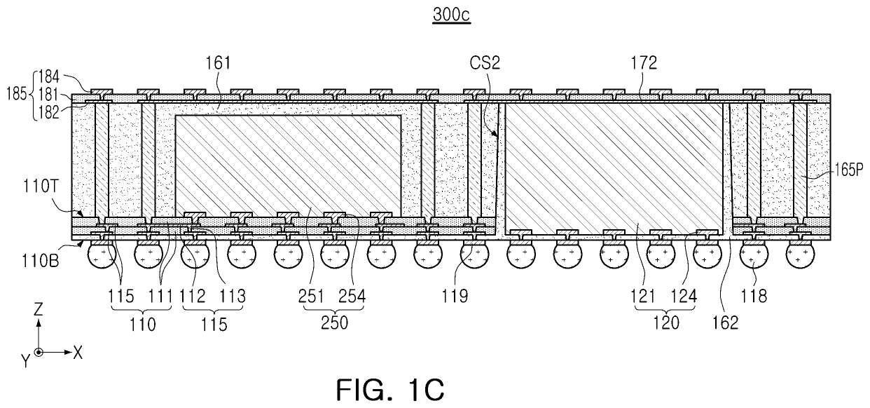

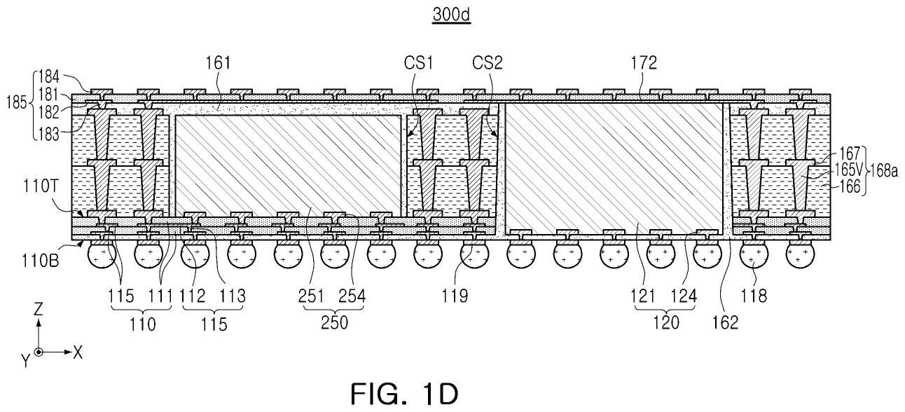

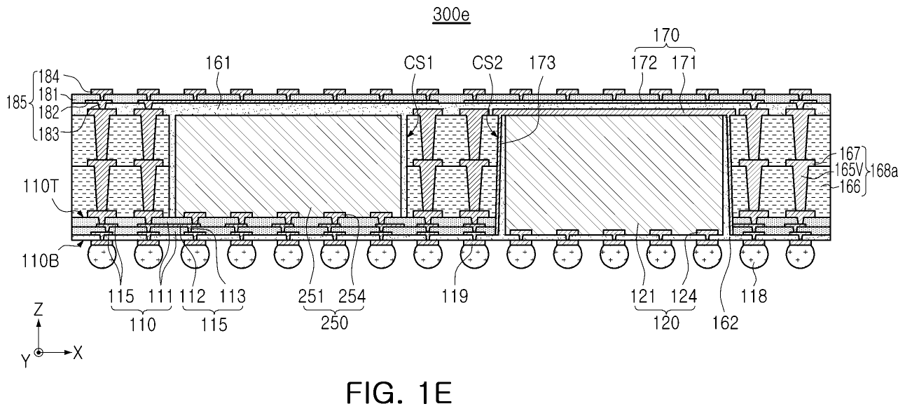

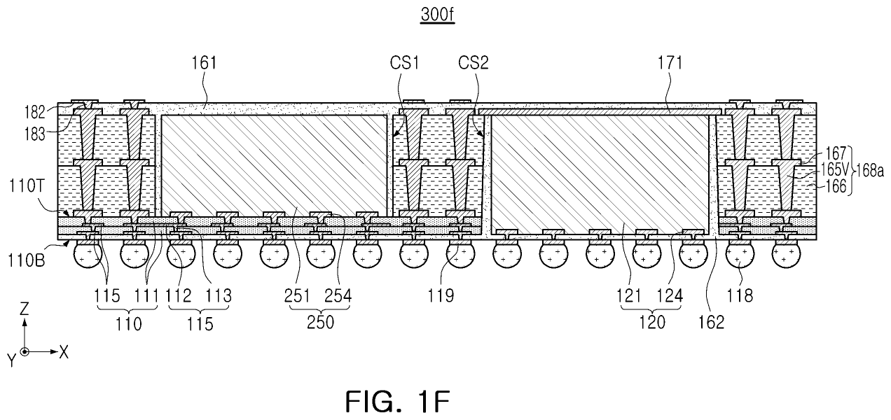

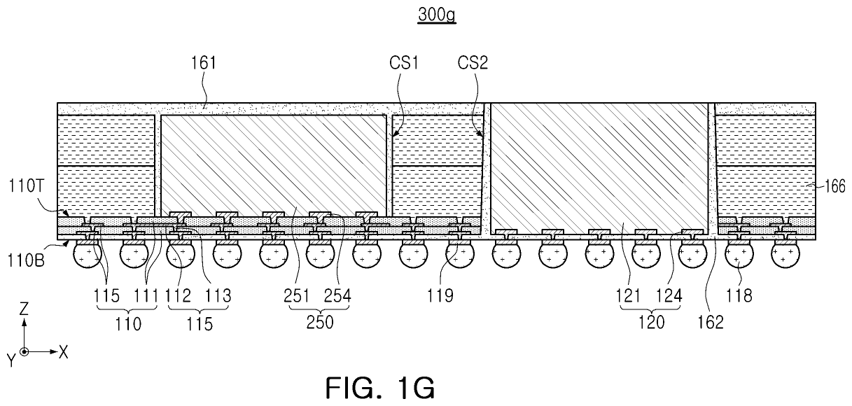

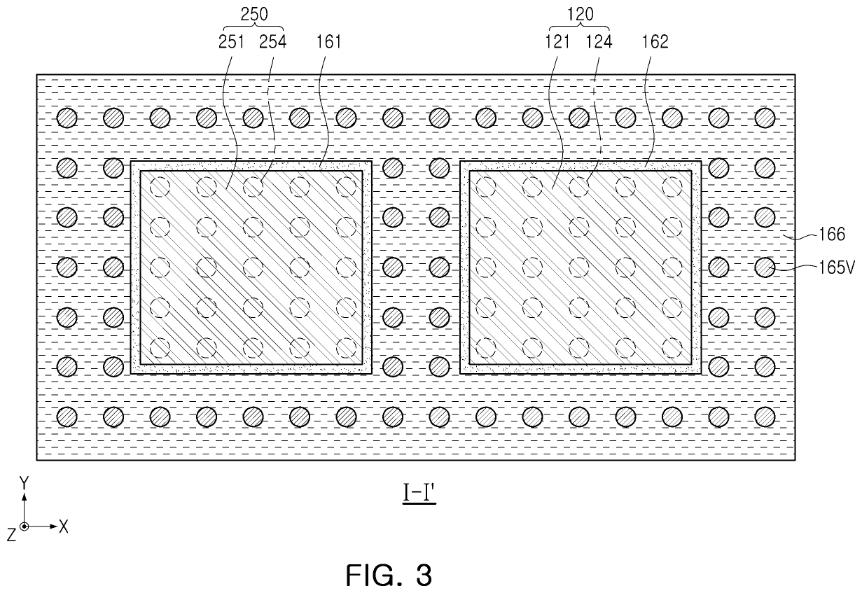

FIGS. 1A to 1G are cross-sectional views illustrating semiconductor packages 300a. 300b, 300c. 300d, 300e, 300f, and 300g, respectively, according to an embodiment, taken along an X-Z plane. FIG. 3 shows a plan view of the semiconductor package 300a of FIG. 1A along a light ranging from I to I′. For example, the semiconductor package may be a system-in-package (SIP) structure including two or more semiconductor chips, or may be a portion of a package-on-package (POP) structure.

Referring to FIG. 1A and FIG. 3, a semiconductor package 300a according to an embodiment may include a first redistribution structure 110, a first semiconductor chip 250, a second semiconductor chip 120, a first encapsulant 161, and a second encapsulant 162. The semiconductor package 300a according to an embodiment may further include at least one of a conductive support layer structure 170, bumps 118, or a core insulating layer 166. The conductive support layer structure 170 may include one or more layers. For example, the conductive support layer structure 170 may include a first conductive support layer 171 and a second conductive support layer 172.

The first redistribution structure 110 may include at least one first insulating layer 111 and a first electrical path 115. The first electrical path 115 may include a first redistribution layer 112 and a first via 113. The first redistribution structure 110 may have a structure in which at least one of the first redistribution layers 112 and at least one of the first insulating layers 111 are alternately layered. The first vias 113 may extend from the at least one first redistribution layer 112 in a layering direction (e.g., a Z-direction) of the first redistribution structure 110. The first vias 113 may pass through the at least one first insulating layer 111.

The at least one first insulating layer 111 may include an insulating material. For example, the at least one first insulating layer 111 may include a thermosetting resin such as an epoxy resin, or a thermoplastic resin such as polyimide. In another example, the at least one first insulating layer 111 may include a photosensitive insulating material such as a photoimageable dielectric (PID) resin. In yet another example, the at least one insulating layer 111 may include a resin mixed with an inorganic filler, for example, an Ajinomoto build-up film (ABF). In still another example, the at least one first insulating layer 111 may include a prepreg, a flame retardant (FR-4), or bismaleimide triazine (BT). The at least one first insulating layer 111 may include a same or different materials, and depending on materials, processes, or the like constituting each layer, a boundary therebetween may not be distinguished. For example, in an example in which two or more first insulating layers 111 are formed, the layers may be formed of the same or different materials.

First redistribution layers 112 and the first vias 113 may form the first electrical paths 115. The first redistribution layers 112 may be disposed in a linear shape on one or more X-Y planes. The first vias 113 may have a cylindrical shape. The first vias 113 may extend in a vertical, Z, direction. Widths of the first vias 113 may become narrow in a downward direction or an upward direction. The first vias 113 are illustrated, respectively, as a filled via structure in which an internal space is completely filled with a conductive material, but are not limited thereto. For example, the first vias 113 may have a conformal via shape, respectively, in which a metal material is formed along an inner wall of a via hole.

The first redistribution layers 112 and the first vias 113 may include a conductive material. The first redistribution layers 112 and the first vias 113 may include, for example, copper (Cu), aluminum (Al), silver (Ag), tin (Sn), gold (Au), nickel (Ni), lead (Pb), titanium (Ti), or alloys thereof.

The first semiconductor chip 250 may be disposed on an upper surface 110T of the first redistribution structure 110. The first semiconductor chip 250 may be electrically connected to the at least one first redistribution layer 112. For example, the first semiconductor chip 250 may include a body portion 251 and connection pads 254. The first semiconductor chip 250 may be electrically connected to the at least one first redistribution layer 112 through the connection pads 254. For example, the connection pads 254 may include a conductive material such as tungsten (W), aluminum (Al), copper (Cu), or the like. The connection pads 254 may be a pad of a bare chip, for example, an aluminum (Al) pad, but may be a pad of a packaged chip, for example, a copper (Cu) pad, according to embodiments.

For example, the first semiconductor chip 250 may include the body portion 251. The body portion 251 may include a semiconductor material such as silicon (Si), germanium (Ge), gallium arsenide (GaAs), or the like. The first semiconductor chip 250 may include a device layer disposed between the body portion 251 and the connection pads 254. The device layer may include, for example, an integrated circuit (IC). The first semiconductor chip 250 may include a logic semiconductor chip and/or a memory semiconductor chip. The logic semiconductor chip may be a microprocessor, such as, a central processing unit (CPU), a graphic processing unit (GPU), a field programmable gate array (FPGA), an application processor (AP), a digital signal processor, a cryptographic processor, a controller, or an application specific integrated circuit (ASIC). The memory semiconductor chip may be a volatile memory such as a dynamic random access memory (DRAM), a static random access memory (SRAM), or the like, or a non-volatile memory such as a flash memory or the like.

A portion of the second semiconductor chip 120 may be surrounded by the first redistribution structure 110. More particularly, the second semiconductor chip 120 may be surrounded by the first redistribution structure 110 in a plan view. For example, the first redistribution structure 110 may have a through-hole in which a portion of the second semiconductor chip 120 is disposed. For example, a lower portion of the second semiconductor chip 120 may be surrounded by the first redistribution structure 110. The second semiconductor chip 120 may be implemented in a manner similar to that of the first semiconductor chip 250, and may include a second body portion 121 and second connection pads 124. For example, the first semiconductor chip 250 may be a logic semiconductor chip, and the second semiconductor chip 120 may be a memory semiconductor chip.

The first encapsulant 161 may be disposed on the upper surface 110T of the first redistribution structure 110. The first encapsulant 161 may encapsulate the first semiconductor chip 250, the second encapsulant 162 may encapsulate the second semiconductor chip 120, and a portion of the second encapsulant 162 may be surrounded by the first redistribution structure 110. More particularly, the second encapsulant 162 may be surrounded by the first redistribution structure 110 in a plan view. For example, the first encapsulant 161 may encapsulate an upper portion of the first semiconductor chip 250 and an upper portion of the second encapsulant 162. Each of the first encapsulant 161 and the second encapsulant 162 may contain a molding material such as an epoxy molding compound (EMC). The material of the first encapsulant 161 and the second encapsulant 162 is not limited to the molding material, and may include an insulating material that may have protective properties similar to those of the molding material or high ductility. For example, the insulating material may be a build-up film (e.g., an Ajinomoto build-up film (ABF)), a thermosetting resin such as an epoxy resin, or a thermoplastic resin such as polyimide. The insulating material may include a material in which an inorganic filler and/or a glass fiber is appropriately added to an insulating material of the first insulating layer 111.

The first encapsulant 161 and the second encapsulant 162 may fill an empty space formed in the semiconductor package 300a as the first semiconductor chip 250 and the second semiconductor chip 120 are embedded in the semiconductor package 300a, and a durability (e.g., robustness against external impact) or a reliability (e.g., preventing internal warpage) of the semiconductor package 300a may be improved.

A size of a space occupied by the first encapsulant 161 and the second encapsulant 162 may increase, as a difference in height between an upper surface of the first semiconductor chip 250 and an upper surface of the second semiconductor chip 120 increases. The difference in height between an upper surface of the first semiconductor chip 250 and an upper surface of the second semiconductor chip 120 may affect a total size of the semiconductor package 300a. Generally, as a difference between a thickness T1 of the first semiconductor chip 250 and a thickness T2 of the second semiconductor chip 120 is reduced, the size of the space occupied by the first encapsulant 161 and the second encapsulant 162 may be reduced, the total size of the semiconductor package 300a may be reduced, and a horizontal balance of the semiconductor package 300a may be improved. The horizontal balance of the semiconductor package 300a may be increased as the difference between a thickness T1 of the first semiconductor chip 250 and a thickness T2 of the second semiconductor chip 120 is decreased. As the horizontal balance is increased, the durability or the reliability of the semiconductor package 300a may be increased.

As a degree of freedom in design of the first semiconductor chip 250 and the second semiconductor chip 120 increases, a difference in performance or role between the first semiconductor chip 250 and the second semiconductor chip 120 may be increased, the difference between the thickness T1 of the first semiconductor chip 250 and the thickness T2 of the second semiconductor chip 120 may be increased, and the size of the space occupied by the first encapsulant 161 and the second encapsulant 162 may be increased. In some cases, miniaturization efficiency, durability, and reliability of the semiconductor package 300a may be balanced against the degree of freedom in design of the first semiconductor chip 250 and the second semiconductor chip 120.

In the semiconductor package 300a according to an embodiment, the first semiconductor chip 250 and the first encapsulant 161 may be disposed on the upper surface 110T of the first redistribution structure 110, and a portion of the second semiconductor chip 120 and a portion of the second encapsulant 162 may include a structure surrounded by the first redistribution structure 110. For example, the semiconductor package 300a according to an embodiment may have a structure in which the difference in height between the upper surface of the first semiconductor chip 250 and the upper surface of the second semiconductor chip 120 may be reduced, even in a case where the difference between the thickness T1 of the first semiconductor chip 250 and the thickness T2 of the second semiconductor chip 120 is large, for example, between about 10 μm and 100 μm). For example, the semiconductor package 300a according to an embodiment may increase a degree of freedom in design of the first semiconductor chip 250 and the second semiconductor chip 120 while improving miniaturization efficiency, durability, and reliability of the semiconductor package 300a. Further, a difference in height between the upper surfaces of the first semiconductor chip 250 and the second semiconductor chip 120 and the upper surface of the semiconductor package 300a may be reduced, a heat generation path of the first semiconductor chip 250 and the second semiconductor chip 120 may be shortened, and overall thermal performance of the first semiconductor chip 250 and second semiconductor chip 120 may be improved.

The conductive support layer structure 170 may support the second semiconductor chip 120 and the second encapsulant 162, and may be formed on upper surfaces of the second semiconductor chip 120 and the second encapsulant 162. The conductive support layer structure 170 may be used in a process of forming a through-hole in the first redistribution structure 110 such that the first redistribution structure 110 surrounds a portion of the second semiconductor chip 120 and a portion of the second encapsulant 162. For example, a portion of the semiconductor package 300a may be removed by, for example, a drill process or a process of colliding fine particles. The process of removing a portion of the semiconductor package 300a may be applied to a portion of a lower surface 110B of the first redistribution structure 110. In this case, the conductive support layer structure 170 may stop a process of removing a portion of the semiconductor package 300a. For example, the conductive support layer structure 170 may be expressed as a stop layer.

The conductive support layer structure 170 may be, for example, a copper foil layer, such as a copper clad laminate (CCL), a carrier release copper foil layer, or a redistribution layer. The conductive support layer structure 170 may be implemented as, for example, a plate having a shape (e.g., a polygonal shape) corresponding to a shape of an upper surface of the second semiconductor chip 120.

Some of the bumps 118 may be electrically connected to the first semiconductor chip 250, and different ones of the bumps 118 may be electrically connected to the second semiconductor chip 120. A first lower portion of the second encapsulant 162 may be disposed between the bumps 118 and the second semiconductor chip 120. For example, the first lower portion of the second encapsulant 162 may be disposed between the bumps 118 and the second semiconductor chip 120 in the Z direction. A second lower portion of the second encapsulant 162 may be disposed between the bumps 118 and the first redistribution structure 110. For example, the second lower portion of the second encapsulant 162 may be disposed between the bumps 118 and the first redistribution structure 110 in the X direction.

Since the second semiconductor chip 120 may be disposed in the semiconductor package 300a through the upper surface of the second semiconductor chip 120, a lower surface of the second semiconductor chip 120 may be exposed to the second encapsulant 162 when the second encapsulant 162 is formed. For example, a portion of the second encapsulant 162 may be disposed between the different ones of the bumps 118 and the second semiconductor chip 120.

The second semiconductor chip 120 may bypass the first redistribution structure 110, and may be connected to the different ones of the bumps 118. For example, an electrical path between the second semiconductor chip 120 and the bumps 118 may not be affected by the first redistribution structure 110 (e.g., a width, a pitch, and a thickness of a redistribution), and may thus have a high degree of freedom in design. For example, when the second semiconductor chip 120 has a high power capacity like a power management integrated circuit (PMIC), a width, a pitch, and a thickness of the electrical path between the second semiconductor chip 120 and the bumps 118 may be greater than a width, a pitch, and a thickness of the first redistribution layer 112 and the first vias 113. For example, a degree of freedom in design of the first semiconductor chip 250 and the second semiconductor chip 120 may be increased, and performance (e.g., signal integrity and power integrity) of the semiconductor package 300a may be improved.

In addition, since a portion of the second encapsulant 162 may be disposed between ones of the bumps 118 and the first redistribution structure 110, a difference in characteristics between different ones of the bumps 118 may be reduced, and overall reliability of the bumps 118 may be improved.

The bumps 118 may have, for example, a ball shape or a column shape. The bumps 118 may include, for example, a solder containing tin (Sn) or an alloy (Sn—Ag—Cu) containing tin (Sn). Since the bumps 118 may have a relatively low melting point, compared to other metal materials, the bumps 118 may be connected and attached to UBMs 119 of the semiconductor package 300a. The bumps 118 may be connected and attached to UBMs 119 of the semiconductor package 300a by a thermal compression bonding (TCB) process or a reflow process. The UBMs 119 may be disposed on the lower surface 110B of the first redistribution structure 110. The UBMs 119 may have a width, wider than a line width of a redistribution layer, such as a pad. The UBMs 119 may have upper/lower surfaces having a generally circular shape. The UBMs 119 may be coupled to a via and may be formed by a semi additive process (SAP).

The core insulating layer 166 may have a first cavity CS1 in which the first semiconductor chip 250 is disposed and a second cavity CS2 in which the second semiconductor chip 120 is disposed, and may be disposed on the upper surface 110T of the first redistribution structure 110. The core insulating layer 166 may be thicker than the first insulating layer 111, and may have greater rigidity than the first insulating layer 111. In an example in which the core insulating layer 166 is thicker than the first insulating layer 111, the core insulating layer 166 may reduce a possibility of warpage of the semiconductor package 300a. The core insulating layer 166 may include an insulating material, similar to an insulating material of a core disposed in a central portion of a printed circuit board, and may be formed by removing a portion of a copper clad laminate (CCL) (corresponding to the first cavity CS1 and the second cavity CS2).

For example, since the first cavity CS1 may be formed to pass through the core insulating layer 166 before an additional structure is disposed on upper and lower surfaces of the core insulating layer 166, a side surface of the first cavity CS1 may be provided at or near a vertical direction. Since the second cavity CS2 may be formed below an additional structure (e.g., the conductive support layer structure 170, the second redistribution structure 185, or the like) after the addition structure is disposed on the upper surface of the core insulating layer 166, a side surface of the second cavity CS2 may be provided at a sloped angle. For example, the side surface of the second cavity CS2 may have a slope, lower than a slope of the side surface of the first cavity CS1. That is, the slope of the side surface of the second cavity CS2 may be closer to the horizontal, or zero degrees, than the slope of the side surface of the first cavity CS1. More particularly, the slope of the side surface of the first cavity CS1 may be closer to vertical in the Z direction than the slope of the side surface of the second cavity CS2.

Referring to FIG. 1A and FIG. 1B, a semiconductor package (300a and 300b) according to an embodiment may include a core member (168a and 168b), and the core member (168a and 168b) may include at least one of a conductive core via 165V, the core insulating layer 166, or a core wiring layer 167, and may be formed according to a panel level package (PLP) method.

The conductive core via 165V may vertically pass through the core insulating layer 166. The core wiring layer 167 may be vertically connected to the conductive core via 165V. For example, the conductive core via 165V and the core wiring layer 167 may be implemented in a manner similar to a conductive structure (e.g., a wiring and a via) of a printed circuit board.

In an example where the core insulating layer 166 is implemented as a core of a copper clad laminate (CCL), the first conductive support layer 171 may formed of a copper foil layer, such as, a copper clad laminate (CCL). An upper surface of the core insulating layer 166 and a lower surface of the first conductive support layer 171 may be located on the same height as each other. In this case, the same height may mean substantially the same height, and a height difference corresponding to a thin thickness of several tens of nanometers, such as an organic release layer of CCL, may be included in a range of substantially the same height.

When a first encapsulant 161 is formed, a portion of the first encapsulant 161 may overflow to the upper surface of the core insulating layer 166, such that the first conductive support layer 171 may be disposed between a portion of the first encapsulant 161 and a second semiconductor chip 120. Alternatively, the first encapsulant 161 may be in direct contact with the first conductive support layer 171.

Referring to FIG. 1C and FIG. 1D, a portion of a first encapsulant 161 of a semiconductor package (300c and 300d) according to an embodiment may surround a portion of a second encapsulant 162 and a portion of a second semiconductor chip 120. The first encapsulant 161 may be in direct contact with the second encapsulant 162. A thickness of the second semiconductor chip 120 may be increased without substantially increasing a thickness of the semiconductor package (300c and 300d).

A lower surface of the second conductive support layer 172 may be located on a height, equal to or higher than an upper surface of the first encapsulant 161. For example, the second conductive support layer 172 may be a portion of a carrier release copper foil layer or a portion of a second redistribution layer 182. A carrier may be temporarily disposed on an upper surface of the semiconductor package (300c and 300d) when the bumps 118 and the second cavity CS2 are formed.

Referring to FIGS. 1A to 1D, a semiconductor package (300a, 300b, 300c, and 300d) according to an embodiment may further include a second redistribution structure 185. The second redistribution structure 185 may be electrically connected to a first redistribution structure 110. The second redistribution structure 185 may have a structure in which at least one second redistribution layer 182 and at least one second insulating layer 181 are alternately layered. The second redistribution structure 185 may further include second vias 183. The second vias 183 may be vertically connected to the at least one second redistribution layer 182. and The second vias 183 may pass through the at least one second insulating layer 181. The second redistribution structure 185 may further include a second UBM 184 electrically connected to the second vias 183. The second UBM 184 may be disposed on an upper surface of the second insulating layer 181 of the second redistribution structure 185. The second redistribution structure 185 may be implemented in a manner similar to the first redistribution structure 110, where the second redistribution layers 182 may be implemented in a manner similar to first redistribution layers 112, the second insulating layers 181 may be implemented in a manner similar to first insulating layers 111, and the second vias 183 may be implemented in a manner similar to first vias 113.

Referring to FIG. 1C, a semiconductor package 300c according to an embodiment may include conductive posts 165P, and may not include a core insulating layer. The conductive posts 165P may vertically connect between a second redistribution structure 185 and a first redistribution structure 110, and may pass through a first encapsulant 161. The conductive posts 165P may be formed prior to formation of the first encapsulant 161, and may be formed by a process of plating a metal material (e.g., copper) in a through-hole of a photo resist temporarily formed prior to formation of the first encapsulant 161, or a process of filling a conductive paste in the through-hole of the photo resist. The semiconductor package 300c may be formed according to, for example, a wafer level package (WLP) method.

The second encapsulant 162 may be formed after the formation of the first encapsulant 161, and a boundary surface between the first encapsulant 161 and the second encapsulant 162 may be based on a difference in formation time between the first encapsulant 161 and the second encapsulant 162. Depending on a design, the boundary surface between the first encapsulant 161 and the second encapsulant 162 may be formed of the same or different materials.

Referring to FIG. 1E, a semiconductor package 300e according to an embodiment may further include a conductive shielding wall 173. The conductive shielding wall 173 may be connected to the first conductive support layer 171 and may surround at least a portion of the second encapsulant 162 and a portion of the second semiconductor chip 120. The conductive shielding wall 173 may improve a degree of electromagnetic isolation between the second semiconductor chip 120 and an external space, and may improve a degree of electromagnetic isolation between the first semiconductor chip 250 and the second semiconductor chip 120. For example, the conductive shielding wall 173 may be formed by a plating process after the second cavity CS2 is formed, or may be implemented as a portion of the conductive core via 165V.

Referring to FIG. 1F and FIG. 1G, a semiconductor package (300f and 300g) according to an embodiment may not include a second redistribution structure. In this case, a first encapsulant 161 may form at least a portion of an upper surface of the semiconductor package (300f and 300g).

Referring to FIG. 1G, a semiconductor package 300g according to an embodiment may not include a conductive support layer. In this case, the second cavity CS2 may be formed in a state in which a carrier is temporarily disposed on an upper surface of the semiconductor package 300g.

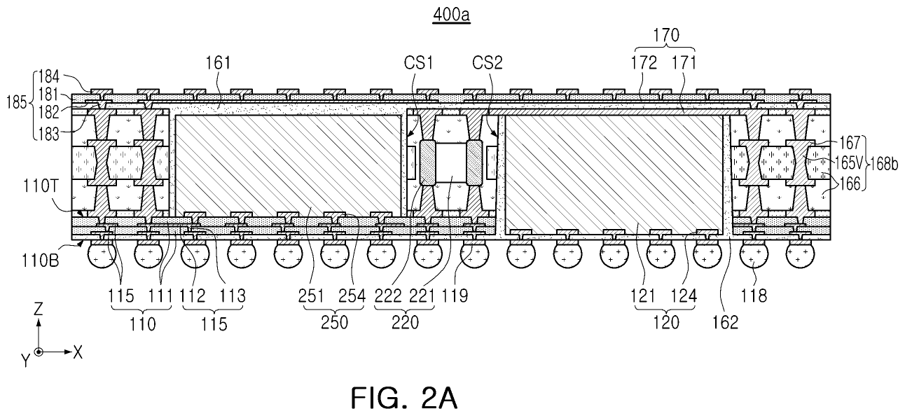

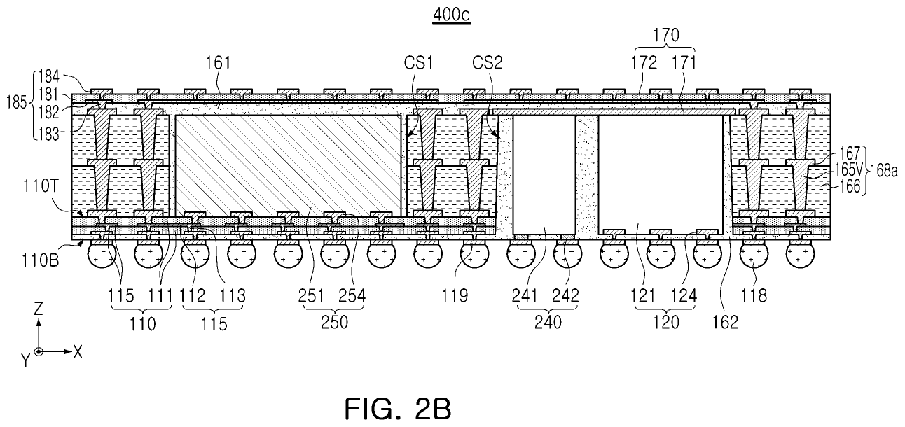

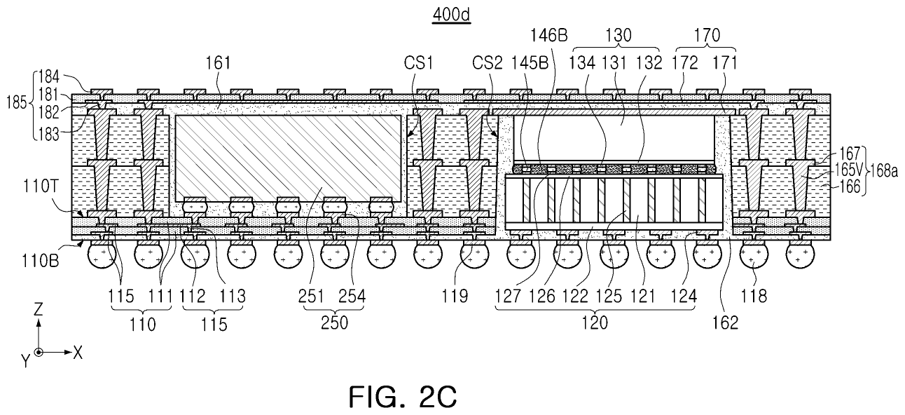

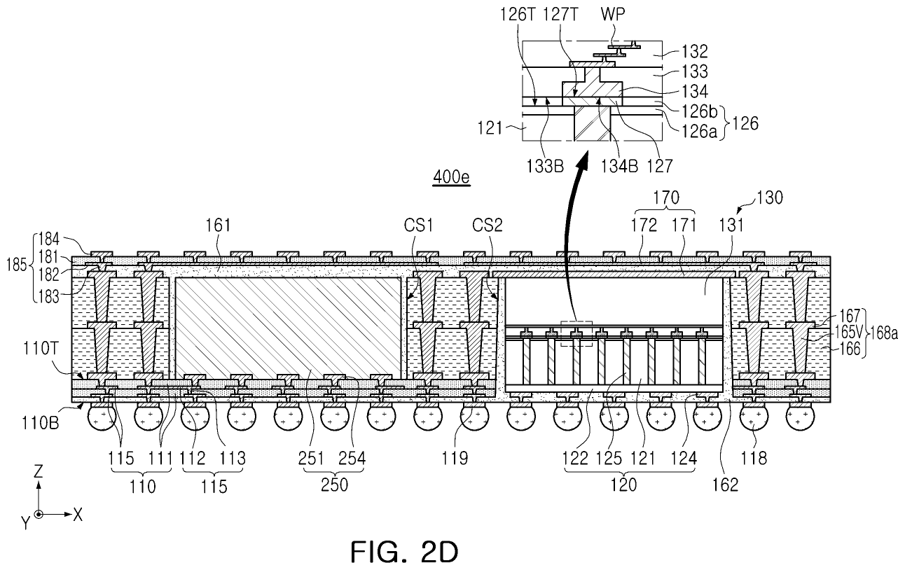

FIGS. 2A to 2D are cross-sectional views illustrating semiconductor packages 400a, 400c, 400d, and 400c, respectively, according to an embodiment, taken along an X-Z plane. For example, the semiconductor package may be a system-in-package (SIP) structure including two or more semiconductor chips, or may be a portion of a package-on-package (POP) structure.

Referring to FIG. 2A and FIG. 2B, a semiconductor package (400a and 400c) according to an embodiment may further include a passive component (220 and 240). For example, the passive component (220 and 240) may be a component that provides impedance, such as a capacitor component or a coil component. The passive component (220 and 240) may passively operate with respect to an operation of a first semiconductor chip 250. For example, the passive component (220 and 240) may include a main body (221 and 241) that may provide an impedance, and may include a terminal (222 and 242) electrically connected to a first redistribution structure 110.

Referring to FIG. 2A, the passive component 220 may be embedded in a core insulating layer 166 among core insulating layers 166. For example, a portion of a core insulating layer 166 among the core insulating layers 166 may be drilled by a drilling process or the like, and the passive component 220 may be disposed in a portion of the core insulating layer 166 among the core insulating layers 166. One or more additional core insulating layers 166 among the core insulating layers 166 may be layered on upper and lower sides of the passive component 220. A thickness of the passive component 220 may be thinner than a thickness of the first semiconductor chip 250.

Referring to FIG. 2B, the passive component 240 may be disposed in a portion of the second cavity CS2. The semiconductor package 400c may have a structure advantageous for embedding a thick passive component (e.g., a power inductor component). Depending on a design, an arrangement of the passive component 240 may be disposed in a portion of the first cavity CS1.

Referring to FIG. 2C and FIG. 2D, second semiconductor chips of a semiconductor package (400d and 400e) according to an embodiment may include second semiconductor chips 120 and 130. The second semiconductor chips 120 and 130 may overlap each other in a direction facing the conductive support layer structure 170. A combined thickness of the second semiconductor chips 120 and 130 may be thicker than a thickness of a first semiconductor chip 250. Depending on a design, a thickness of one second semiconductor chip, among the second semiconductor chips 120 and 130, disposed in the second cavity CS2 may be less than or equal to the thickness of the first semiconductor chip 250.

Referring to FIG. 2C, the first semiconductor chip 250 may be electrically connected to the first redistribution structure 110 via bumps disposed on the first redistribution structure 110. The upper surface of the first semiconductor chip 250 disposed on the bumps may have a same height as the upper surface of the second semiconductor chips 120 and 130. The first semiconductor chip 250 may be encapsulated by the first encapsulant 161. For example, the first encapsulant 161 may be disposed on the upper surface of the first semiconductor chip 250, on side surfaces of the first semiconductor chip 250, and on a lower surface of the first semiconductor chip 250.

Referring to FIG. 2C and FIG. 2D, the second semiconductor chip 120 and 130 may include one or more of second body portions 121, third body portions 131, device layers 122 and 132, through-vias 125, first intermediate dielectric layer 126, second intermediate dielectric layer 133, first connection pads 127, second connection pads 134, second bumps 145B, or a non-conductive film layer 146B.

The second bumps 145B may electrically connect the second semiconductor chips 120 and 130, and may be implemented in a manner similar to bumps 118. The second bumps 145B may be smaller than each of the bumps 118.

The first connection pads 127 and the first intermediate dielectric layer 126 may be disposed on an upper surface of the second semiconductor chip 120. The second bumps 145B may be in contact with and be disposed between the first connection pads 127 and the second connection pads 134. The through-vias 125 may pass through the second body portion 121, and may be electrically connected between the device layer 122 and the first connection pads 127. The through-vias 125 may be formed of a conductive material, and may include, for example, at least one of tungsten (W), aluminum (Al), or copper (Cu).

The non-conductive film layer 146B may surround the second bumps 145B. For example, the non-conductive film layer 146B may be referred to as an underfill layer, and may include a non-conductive polymer, such as a non-conductive paste (NCP).

The first connection pads 127 and the second connection pads 134 may be in contact with each other, and the first intermediate dielectric layer 126 and the second intermediate dielectric layer 133 may be in contact with each other. For example, the first connection pads 127 and the second connection pads 134 may be covered by the first intermediate dielectric layer 126 and the second intermediate dielectric layer 133, and may not be exposed through the second encapsulant 162. This structure may be expressed as hybrid bonding. For example, each of the first intermediate dielectric layer 126 and second intermediate dielectric layer 133 may include at least one of silicon oxide (SiO), silicon nitride (SiN), or silicon carbonitride (SiCN).

The first intermediate dielectric layer 126 and the second intermediate dielectric layer 133 may be disposed on the second semiconductor chip 120 and the second semiconductor chip 130, respectively, before the second semiconductor chip 120 and the second semiconductor chip 130 are bonded. The second semiconductor chip 120 and the second semiconductor chip 130 may be joined to each other through a boundary surface 133B of the first intermediate dielectric layer 126 and the second intermediate dielectric layer 133. In this case, the first connection pads 127 and the second connection pads 134 may be joined to each other through boundary surfaces 127T and 134B.

The first intermediate dielectric layer 126 may include a plurality of intermediate dielectric layers 126a and 126b, and the plurality of intermediate dielectric layers 126a and 126b may be joined to each other through a boundary surface 126T. Upper surfaces of the through-vias 125 and the boundary surface 126T may form a plane. For example, the upper surfaces of the through-vias 125 and the boundary surface 126T may form the same plane. The second connection pads 134 may be connected to a wiring pattern WP of the device layer 132.

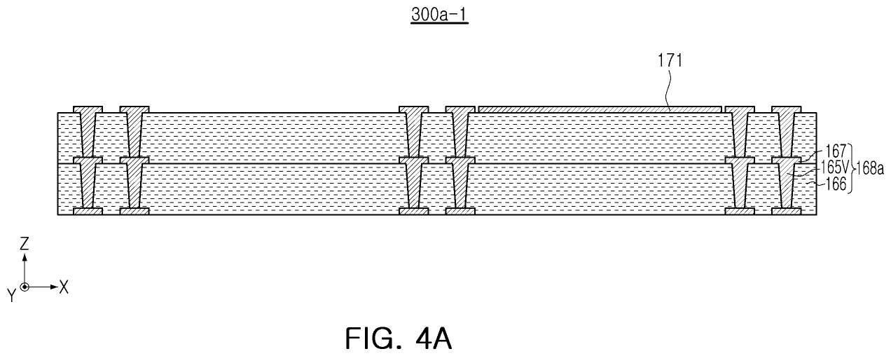

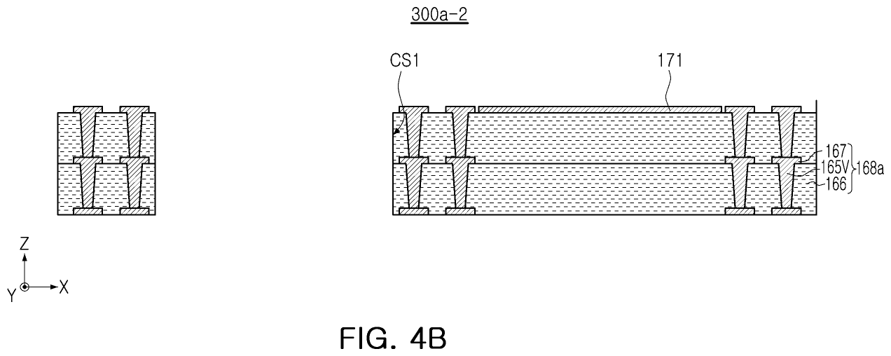

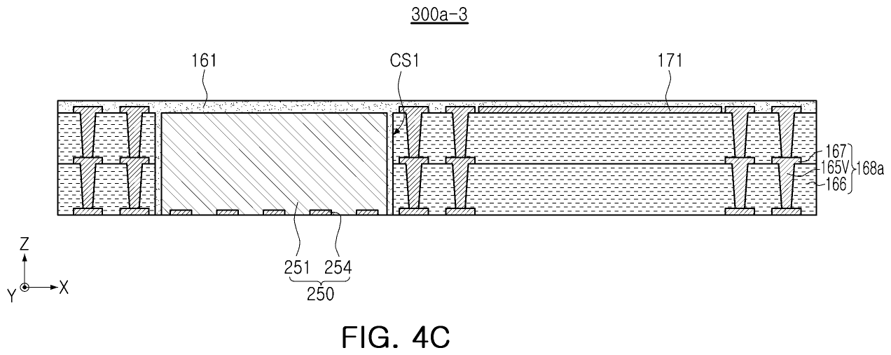

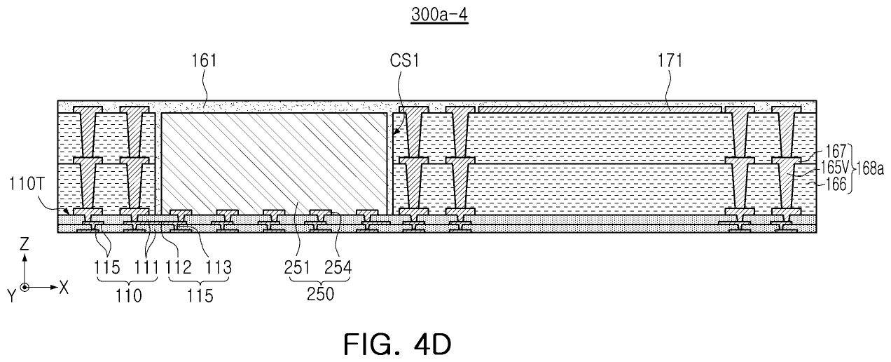

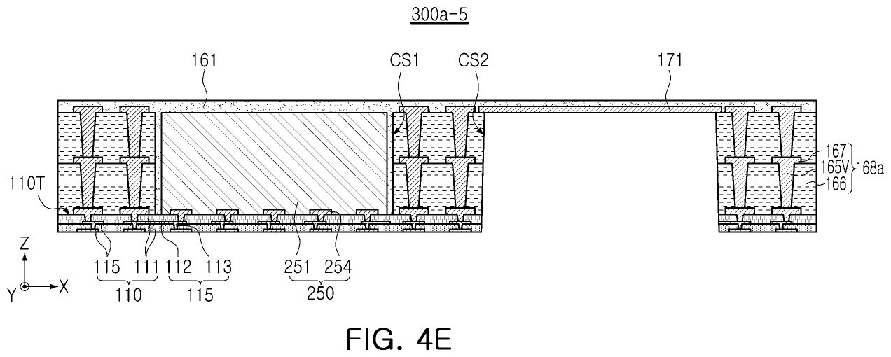

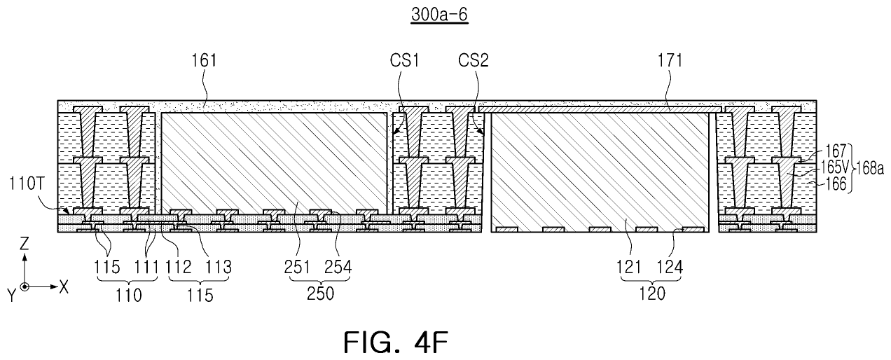

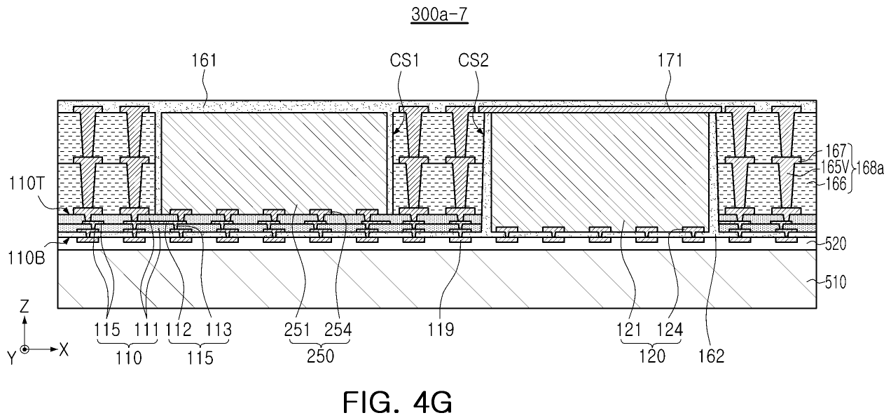

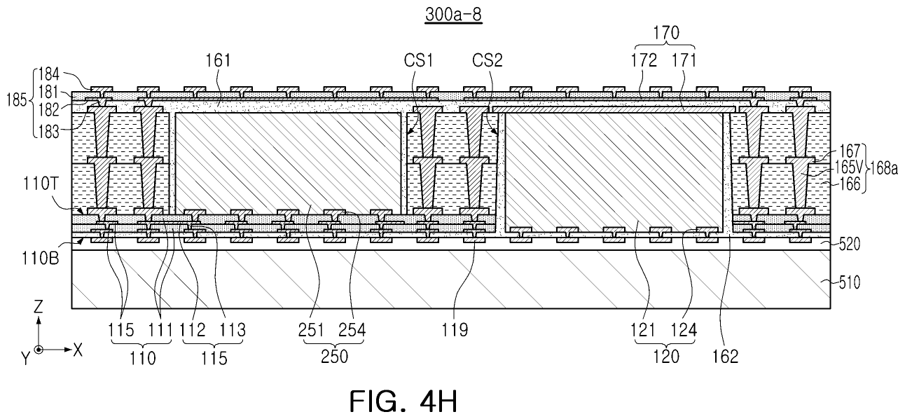

Referring to FIGS. 4A to 4H, according to an embodiment, in a method of manufacturing a semiconductor package, the semiconductor package 300a of FIG. 1A may be manufactured in a sequence from a first structure 300a-1 to an eighth structure 300a-8. It should be understood that the semiconductor package 300a of FIG. 1A is not limited by methods of manufacturing the semiconductor package shown in FIGS. 4A to 4H.

The first structure 300a-1 may include the core insulating layer 166 and the first conductive support layer 171. The core insulating layer 166 may include one or more layers, sequentially formed. The first structure 300a-1 may further include a core wiring layer 167 and a conductive core via 165V. For example, a process of forming the core wiring layer 167 and the conductive core via 165V may use a structure containing a material that may be exposed and developed, such as a photoresist. For example, the core wiring layer 167 may be patterned to formed openings in which the conductive core via 165V may be formed. In addition, the core wiring layer 167 may be formed by depositing and patterning a conductive material on an upper surface of a layer of the core insulating layer 166. These processes may be repeated to form a multi-layer structure including, for example, layers of the core insulating layer 166.

Referring to FIG. 4B, the second structure 300a-2 may have a structure in which the first cavity CS1 is formed. For example, the first cavity CS1 may be formed by a drill process or a process of colliding fine particles (e.g., sand blast). Referring to FIG. 4C, the third structure 300a-3 may further include the first semiconductor chip 250 and the first encapsulant 161 disposed in the first cavity CS1.

Referring to FIG. 4D, the fourth structure 300a-4 may further include the first redistribution structure 110. For example, a process of forming the first redistribution structure 110 may use a structure containing a material that may be exposed and developed, such as a photoresist. Referring to FIG. 4E, the fifth structure 300a-5 may have a structure in which the second cavity CS2 may be formed. Referring to FIG. 4F, the sixth structure 300a-6 may have a structure in which the second semiconductor chip 120 may be disposed in the second cavity CS2. For example, the second cavity CS2 may be formed by a drill process or a process of colliding fine particles (e.g., sandblasting).

Referring to FIG. 4G, the seventh structure 300a-7 may have a structure in which the second encapsulant 162 may be disposed in the second cavity CS2 surrounding a portion of the second semiconductor chip 120, and UBMs 119 may be formed on the first redistribution structure 110. The seventh structure 300a-7 may have a structure in which a carrier substrate 510 may be disposed on a lower surface of the second encapsulant 162 and the UBMs 119 through an adhesive layer 520. For example, the carrier substrate 510 may be a detachable copper foil (DCF) carrier substrate, temporarily disposed on the lower surface of the second encapsulant 162. Referring to FIG. 4H, the eighth structure 300a-8 may further include the second redistribution structure 185. The carrier substrate 510 and the adhesive layer 520 may be removed, and bumps may be formed on the UBMs 119.

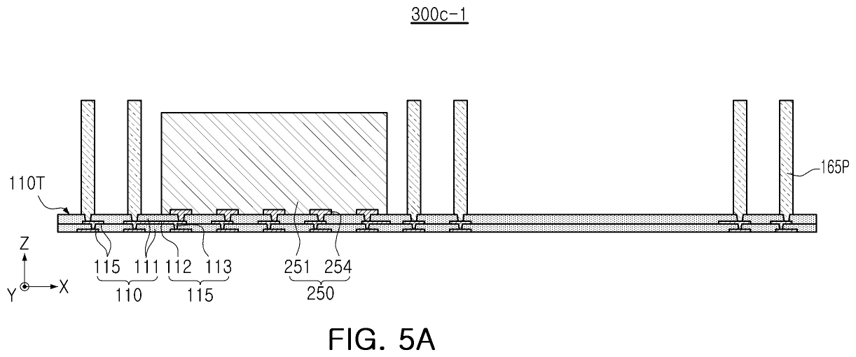

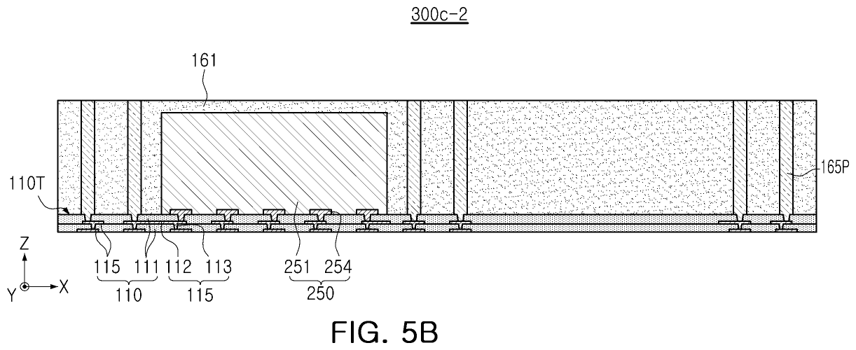

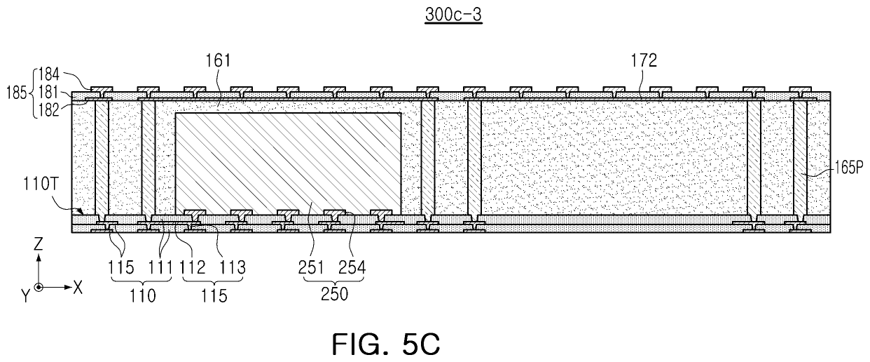

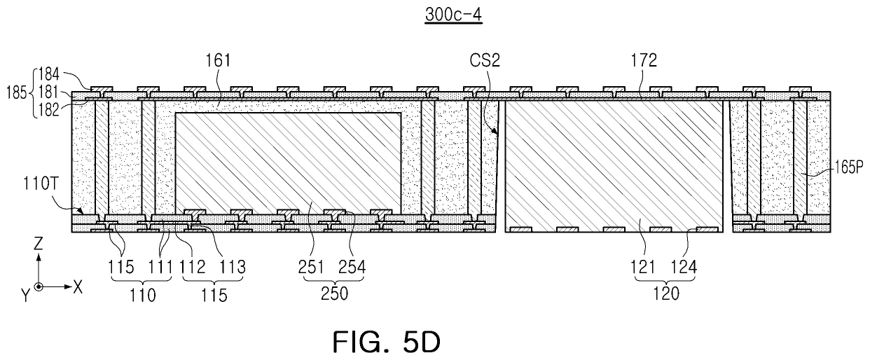

Referring to FIGS. 5A to 5D, according to a method of manufacturing a semiconductor package according to an embodiment, the semiconductor package 300c of FIG. 1C may be manufactured in a sequence from a first structure 300c-1 to a fourth structure 300c-4. It should be understood that the semiconductor package 300c of FIG. 1C is not limited to methods of manufacturing the semiconductor package shown in FIGS. 5A to 5D.

Referring to FIG. 5A, the first structure 300c-1 may include a first redistribution structure 110, and may include the first semiconductor chip 250 and the conductive posts 165P, disposed on the upper surface 110T of the first redistribution structure 110. Referring to FIG. 5B, the second structure 300c-2 may further include the first encapsulant 161. For example, a process of forming the first redistribution structure 110 may use a structure containing a material that may be exposed and developed, such as a photoresist.

Referring to FIG. 5C, the third structure 300c-3 may further include the second redistribution structure 185 and/or the second conductive support layer 172. Referring to FIG. 5D, the fourth structure 300c-4 may have a structure in which the second cavity CS2 is formed, and may include the second semiconductor chip 120 disposed in the second cavity CS2. For example, the second cavity CS2 may be formed by a drill process or a process of colliding fine particles (e.g., sand blast). Then, the second encapsulant 162 (not shown) may be formed to encapsulate the second semiconductor chip 120, and bumps may be further formed.

A semiconductor package according to an embodiment may increase a degree of freedom in design of semiconductor chips and may be advantageously enable at least one of miniaturization efficiency, durability, or reliability.

While embodiments have been shown and described above, it will be apparent to those skilled in the art that modifications and variations could be made without departing from the scope of the present inventive concept as defined by the appended claims.

What is claimed is:

1. A semiconductor package comprising:
a first redistribution structure in which at least one first redistribution layer and at least one first insulating layer are alternately layered;
a first semiconductor chip disposed on an upper surface of the first redistribution structure;
a second semiconductor chip having a lower portion surrounded by the first redistribution structure;
a first encapsulant disposed on the upper surface of the first redistribution structure to encapsulate the first semiconductor chip;
a second encapsulant encapsulating the second semiconductor chip and having a lower portion surrounded by the first redistribution structure; and
a conductive support layer supporting the second semiconductor chip and the second encapsulant on an upper surface of the second semiconductor chip.

2. The semiconductor package of claim 1,
wherein the first encapsulant is in direct contact with at least one of the conductive support layer and the second encapsulant.

3. The semiconductor package of claim 1, wherein the first encapsulant surrounds an upper portion of the second encapsulant and an upper portion of the second semiconductor chip.

4. The semiconductor package of claim 3, wherein a lower surface of the conductive support layer is disposed at a height, equal to or higher than an upper surface of the first encapsulant.

5. The semiconductor package of claim 1, further comprising a core insulating layer comprising:
a first cavity in which the first semiconductor chip is disposed; and
a second cavity in which the second semiconductor chip is disposed, and disposed on the upper surface of the first redistribution structure.

6. The semiconductor package of claim 5, wherein the first encapsulant is disposed on an upper surface of the core insulating layer and surrounds an upper portion of the second encapsulant and an upper portion of the second semiconductor chip, and
a lower surface of the conductive support layer is disposed at a height, equal to or higher than an upper surface of the first encapsulant.

7. The semiconductor package of claim 5, wherein an upper surface of the core insulating layer and a lower surface of the conductive support layer are disposed at a same height as each other.

8. The semiconductor package of claim 5, wherein the conductive support layer is disposed between a portion of the first encapsulant and the second semiconductor chip.

9. The semiconductor package of claim 5, wherein a slope of a side surface of the second cavity is lower than a slope of a side surface of the first cavity.

10. The semiconductor package of claim 1, further comprising:
a plurality of core insulating layers having a first cavity in which the first semiconductor chip is disposed and a second cavity in which the second semiconductor chip is disposed, and disposed on the upper surface of the first redistribution structure; and
a passive component embedded in a core insulating layer among the plurality of core insulating layers.

11. The semiconductor package of claim 1, further comprising a conductive shielding wall connected to the conductive support layer and surrounding the second semiconductor chip and at least a portion of the second encapsulant.

12. The semiconductor package of claim 1, further comprising:
a second redistribution structure in which at least one second redistribution layer and at least one second insulating layer are alternately layered and disposed on an upper surface of the first semiconductor chip and the upper surface of the second semiconductor chip; and
a plurality of conductive posts connecting between the first redistribution structure and the second redistribution structure.

13. The semiconductor package of claim 1, wherein a thickness of the second semiconductor chip is thicker than a thickness of the first semiconductor chip.

14. The semiconductor package of claim 1, wherein the second semiconductor chip comprises a plurality of second semiconductor chips overlapping each other in a direction facing the conductive support layer, wherein a combined thickness of the second semiconductor chips is greater than a thickness of the first semiconductor chip.

15. The semiconductor package of claim 1, further comprising a plurality of bumps having a first set of the plurality of bumps electrically connected to the first semiconductor chip and a second set of the plurality of bumps electrically connected to the second semiconductor chip, and
the second set of the plurality of bumps bypasses the first redistribution structure to be electrically connected to the second semiconductor chip.

16. The semiconductor package of claim 1, further comprising a plurality of bumps having a first set of the plurality of bumps electrically connected to the first semiconductor chip and a second set of the plurality of bumps electrically connected to the second semiconductor chip,
a first portion of the lower portion of the second encapsulant is disposed between the second set of the plurality of bumps and the second semiconductor chip,
a second portion of the lower portion of the second encapsulant is disposed between the second set of the plurality of bumps and the first redistribution structure, and
an upper portion of the second encapsulant is disposed between the second semiconductor chip and the first redistribution structure.

17. A semiconductor package comprising:
a first redistribution structure in which at least one first redistribution layer and at least one first insulating layer are alternately layered;
a first semiconductor chip disposed on an upper surface of the first redistribution structure;
a second semiconductor chip having a lower portion surrounded by the first redistribution structure;
a first encapsulant disposed on the upper surface of the first redistribution structure to encapsulate the first semiconductor chip;
a second encapsulant encapsulating the second semiconductor chip and having a lower portion surrounded by the first redistribution structure; and
a plurality of bumps having a first set of the plurality of bumps electrically connected to the first semiconductor chip and a second set of the plurality of bumps electrically connected to the second semiconductor chip,
wherein a first portion of the lower portion of the second encapsulant is disposed between the second set of the plurality of bumps and the second semiconductor chip, and
a second portion of the lower portion of the second encapsulant is disposed between the second set of the plurality of bumps and the first redistribution structure.

18. The semiconductor package of claim 17, wherein the first encapsulant is in direct contact with the second encapsulant, and
the first encapsulant surrounds an upper portion of the second encapsulant and an upper portion of the second semiconductor chip.

19. The semiconductor package of claim 17, further comprising a core insulating layer comprising:
a first cavity in which the first semiconductor chip is disposed; and
a second cavity in which the second semiconductor chip is disposed, and disposed on the upper surface of the first redistribution structure,
wherein a slope of a side surface of the second cavity has a lower slope than a slope of a side surface of the first cavity.

20. A semiconductor package comprising:
a first redistribution structure in which at least one first redistribution layer and at least one first insulating layer are alternately layered;
a first semiconductor chip disposed on an upper surface of the first redistribution structure;
a second semiconductor chip having a lower portion surrounded by the first redistribution structure;
a core insulating layer having a first cavity in which the first semiconductor chip is disposed and a second cavity in which the second semiconductor chip is disposed, and disposed on the upper surface of the first redistribution structure;
a first encapsulant disposed on the upper surface of the first redistribution structure to encapsulate the first semiconductor chip;
a second encapsulant encapsulating the second semiconductor chip and having a lower portion surrounded by the first redistribution structure;
a conductive support layer supporting the second semiconductor chip and the second encapsulant on an upper surface of the second semiconductor chip; and
a plurality of bumps having a first set of the plurality of bumps electrically connected to the first semiconductor chip and a second set of the plurality of bumps electrically connected to the second semiconductor chip,
wherein a slope of a side surface of the second cavity has a lower slope than a slope of a side surface of the first cavity,
the first encapsulant is in direct contact with the conductive support layer on the second encapsulant,
the first encapsulant is disposed on an upper surface of the core insulating layer,
a first portion of the lower portion of the second encapsulant is disposed between the second set of the plurality of bumps and the second semiconductor chip, and
an upper portion of the second encapsulant is disposed between the second set of the plurality of bumps and the first redistribution structure.
